(19) United States
(12) Patent Application Publication
(10) Pub. No.: US 2006/0046525 A1
(43) Pub. Date: Mar. 2, 2006

(54) Printed circuit board type connector using surface mount and through hole technologies

(76) Inventor: Allan Mark, Manchester, NH (US)

Correspondence Address: NIXON PEABODY, LLP, 401 9TH STREET, NW, SUITE 900, WASHINGTON, DC, 20004-2128, US

(21) Appl. No.: 10/928,001

(22) Filed: Aug. 27, 2004

(51) Int. Cl. H05K 1/00

(52) U.S. Cl. 439/65

(57) ABSTRACT

The invention is a connector which employs both surface mount technology as well as through-hole technology to connect one printed circuit board (PCB) to another. In one embodiment, the connector includes a pair of square prongs the length of which depends on the thickness of the PCB. The height of the connector depends on the needed stand-off height between the two PCBs. The prongs enable fastening of the connector to a first PCB using through-hole technology (THT) by creating an interference fit with the first PCB via holes formed in the first PCB. An predetermined surface of the connector opposite from the surface defined by the first PCB is co-planar with the surface of a second PCB, to enable fastening of the connector to a corresponding area on the surface of the second PCB using surface mount technology (SMT).

### FIELD OF THE INVENTION

The present invention relates to a device for providing a connection between pairs of printed circuit boards (PCBs) and, in particular, to a connector that uses both surface mount technology (SMT) and through-hole technology (THT) for connecting one board to another.

### BACKGROUND OF THE INVENTION

Computers and other electronic devices often include a plurality of interconnected printed circuit boards (PCBs). For example, it is common for a computer to have a motherboard and one or more other boards that execute or perform specialized operations or tasks, such as power conversion, for providing high current power to the motherboard. Connections between such PCBs allow for the transfer of power between boards, and/or for the transfer of information, such as data or control signals. Printed circuit boards can be connected together through use of high current conductor pins mounted or formed on the edges of the PCBs, by mounting cable or ribbon connectors on each board, or by providing pads on pairs of boards to allow for direct board-to-board connection with surface mount technology (SMT) connector terminals or pins. See, e.g., U.S. patent application Ser. No. 10/634,332, which is incorporated herein by reference.

For board-to-board PCB mounting, it is important that the boards are physically separated, yet electrically connected. It is also important that the boards be mechanically supported to prevent excessive movement of the boards. For power boards and boards that otherwise dissipate a large amount of power, the flow of heat between boards is also of concern. The electrical, physical, and mechanical functions can be provided separately, such as by mounting spacing devices to provide separation and mechanical support, and by providing connectors on each board and a cable to establish electrical connections between the connectors. Alternatively, connectors that are designed to mate together can be attached to two boards opposite to each other to provide both electrical connections and physical separation support.

One method of providing electrical and physical functions with a connector is through the use of an SMT connector that allows for connection between opposing surface areas of a pair of PCBs. Prior art SMT connectors have either a box like cross-section or some type of two-dimensional pin arrangement. SMT connectors of the first type are commonly formed of a thin metal sheet bent into a 4-sided, thin-walled structure, where the four sides form a rectangle. The resulting hollow structure has one pair of opposing sides (“attachment sides”) that have approximately equal contact areas for attaching the structure to respective surfaces of its PCB. The other pair of opposing sides provides electrical connections between the attachment sides. These box type connectors allow a module or PCB to be surface mounted to another module or PCB in a mezzanine type of arrangement, also known as board stacking.

The prior art box type SMT connector for PCBs has several advantages over a two-dimensional pin type connector. For example, the box type connector has an aspect ratio that yields a lower parasitic inductance than the two-dimensional pin type connector. Further, the box type connector is more stable as a platform when compared to the two-dimensional pin type connector. Furthermore, the box type connector may allow additional material to be included in the connector, whereas the two-dimensional PIM type connector typically cannot.

But in spite of these advantages over a two-dimensional pin connector, the box type connector usually provides limited mechanical stability. The size of prior art contact pads on a PCB is usually kept small to reduce the contact pad footprint. The spacing of PCB boards is governed by the size of electrical components mounted on the boards and also typically to allow airflow for cooling purposes. Thus, the height dimension of an SMT connector (dictated by the board spacing) is usually much larger than the width dimension (dictated by the contact pad size). Prior art SMT connectors are thus elongated rectangular structures attached to the boards along their smaller sides. As a result, these connectors suffer from a tendency to tip over during assembly processing.

Another key problem with such structures is that these modules typically experience multiple solder reflow processes, not only during initial construction, but also during other assembly steps by the end user. Prior art surface mount technology (SMT) connectors tend to shift into misaligned positions or even fall off the PCB as a consequence of undergoing solder reflow, especially during rework procedures. Once an SMT connector falls off, re-installation is very difficult, if not impossible. In other words, each SMT connector is fully dependent on the solder bond that exists between the SMT connector and the PCB pad on which the SMT connector is mounted. A detached or damaged connector makes the entire board nonfunctional.

Another disadvantage is seen when the SMT connector is used in a power circuit. Typically, connections are made to the power components on the top of the power circuit PCB, while connections to the second PCB are on the bottom of the power circuit PCB. This requires the transmission of power, and thus heat, from one side of the power circuit PCB through to the other. This is usually accomplished with vias, which are small plated holes that pass through the PCB. The vias are not only expensive to create, but also typically are a constriction point in this power/heat flow, resulting in loss of efficiency and an increase in heating. Yet another disadvantage of prior art SMT box connectors is that they are typically supplied to an end user in a tape and reel format, resulting in a considerable increase in cost per component.

What is needed is an improved connector for PCBs that takes advantage of both surface mount technology (SMT) and through-hole technology (THT). Such a connector should provide electrical contact between two PCBs, while providing the amount of spacing required to accommodate the size of components positioned between the PCBs, and also providing mechanical support for the connected PCBs. Further, the connector should be capable of providing sufficient conductive heat transfer between the PCBs. Lastly, the connector should have low parasitic inductance, provide high component retention, and be suitable for efficient automated SMT manufacturing processes, by, for example, by being available in a lower cost continuous coil format. A prior art connector made by Autosplice and another made by Zierick incorporates some of the above mentioned features, but is formed using a two-dimensional flat stamping rather than a combination of three-dimensional cross-section and the use of both THT and SMT.

### SUMMARY OF THE INVENTION

The present invention solves the above-identified problems of known SMT connectors by providing a connector which employs both SMT as well as THT. According to one embodiment of the present invention, the connector achieves a lower parasitic inductance than with known connectors that use two-dimensional or large aspect ratio type designs, thereby enabling higher speed transfer of electrical power through the connector. The connector according to the present invention provides a higher retention capability than with known connectors using SMT. Power connectors using SMT for retention rely on surface tension and adhesion between the solder and the connector to hold the connector to its host PCB. According to the present invention, mechanical interference is used between the connector and the PCB on which the connector is installed, in order to hold the connector in place on the PCB. This provides an assembly process improvement as compared to when connectors using SMT only are used. A further benefit, according the present invention, is that the connector can be provided in a continuous coil format, thereby saving costs.

According to one embodiment of the present invention, the connector includes a pair of prongs. According to another embodiment of the present invention, the length of the prongs is not fixed but rather can be changed depending on the thickness of the PCB to which the connector is attached. The overall height of the connector can also be changed as a function of the stand-off height needed between adjacent PCBs. According to a preferred embodiment of the present invention, each prong has a square cross-sectional shape. According to another embodiment of the present invention, a notch shaped break in the surface of the connector to be connected by surface mounting to a second PCB aids in centering the connector on the surface of said second PCB under solder reflow conditions. According to another embodiment of the present invention, the notch shaped break isolates two sides of the connector for testing purposes.

Broadly stated, the present invention is a connector for connecting a first printed circuit board to another printed circuit board, said connector comprising: a body portion formed of a strip of conductive material bent in a central area thereof to define a curved outer surface and a hollow cross-section and having a first end and a second end, said first end having at least one prong extending out therefrom in a direction opposite to said curved outer surface and sized to be interference fit into a corresponding hole defined in said first printed circuit board, said second end extending approximately in the same direction as said first end, said curved outer surface defining a plane that is approximately co-planer with the surface of said second printed circuit board such that said curved outer surface is enabled to be surface mounted to said second printed circuit board whose surface is approximately coplanar with the adjacent surface of said first printed circuit board.

In addition, the present invention is a connector for connecting a first printed circuit board, said connector comprising: a pair of prongs formed at a first end of said connector; a second end of said connector opposite to said first short end folded towards said first end until said second end is horizontally at a same where said pair of prongs is formed on said first end; and a notch formed on the surface of said connector opposite to said first and second ends in the area of said fold.

A further understanding of the invention can be had from the detailed discussion of the specific embodiments below. For purposes of clarity, this discussion refers to devices, methods, and concepts in terms of specific examples. However, the present invention may be used in a wide variety of devices. It is therefore intended that the invention not be limited by the scope of specific embodiments described below.

### BRIEF DESCRIPTION OF THE DRAWINGS

The foregoing aspects and the attendant advantages of the present invention will become more readily appreciated by reference to the following detailed description, when taken in conjunction with the accompanying drawings, wherein:

FIGS. 1A and 1B show perspective views of a connector according to one embodiment of the present invention;

FIG. 1C is a detailed view of the prongs of the connector shown in FIGS. 1A and 1B press fit inserted according to the present invention into round holes formed in a PCB;

FIGS. 2A-2E show front, top, side, bottom and back views, respectively, of the connector shown in FIG. 1, along with preferred dimensions;

FIG. 3 is a perspective view of a series of SMT connectors, according to another embodiment of the present invention, arranged in a continuous coil format;

FIG. 4 is a perspective view of a pair of rows of connectors according to the present invention installed on a first PCB; and

FIG. 5 is a perspective view of an alternative embodiment of the present invention wherein the connector includes a single tab for press fit insertion into a corresponding PCB slot.

Reference symbols are used in the figures to indicate certain components, aspects or features shown therein, with reference symbols common to more than one figure indicating like components, aspects or features shown therein.

### DETAILED DESCRIPTION OF THE INVENTION

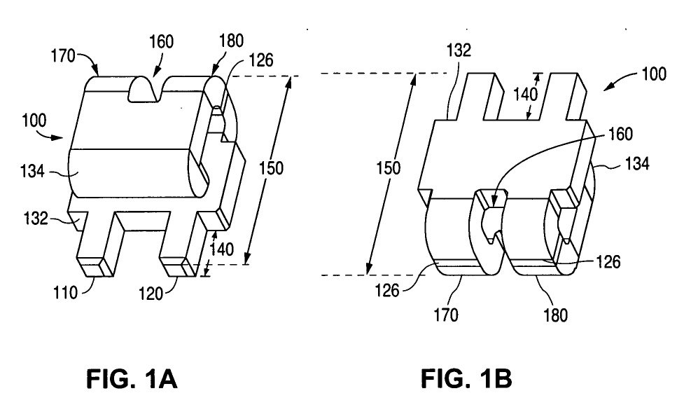

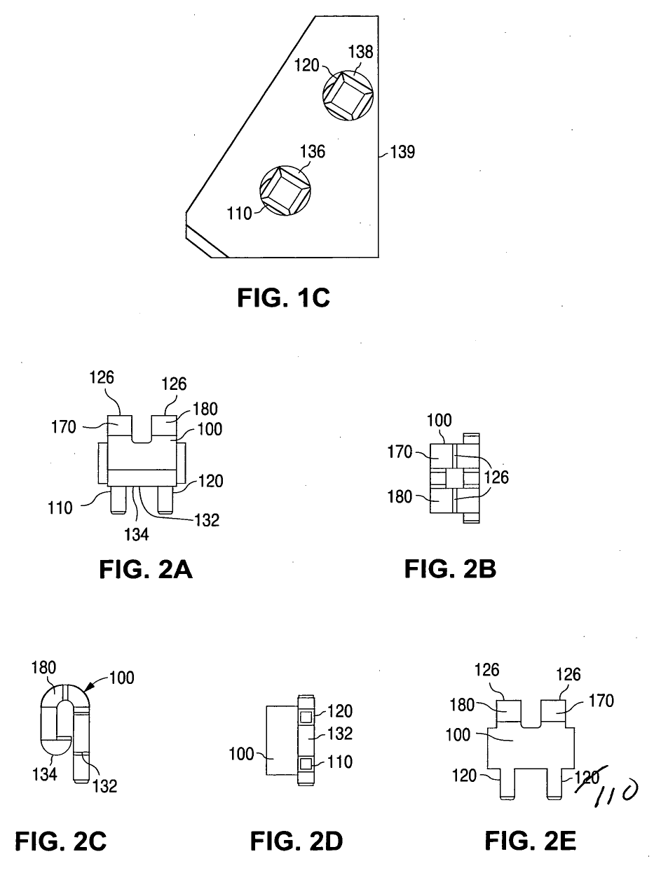

In general, the present invention is a connector that can be connected between two printed circuit boards (PCBs) using both SMT and THT. The present invention will now be described in more detail with reference to the figures. FIGS. 1A and 1B show perspective views of a connector 100 according to the present invention. In particular, these figures show two perspective views of a preferred embodiment of connector 100. Connector 100 is essentially a one piece rectangular shaped component or body portion formed of a strip of conductive material bent in a central area thereof to define a curved outer surface 126 and a hollow cross-section (as best seen in FIG. 2C described below). Connector 100 includes a first end 132 and a second end 134. The first end 132 includes at least one prong 110,120 extending out from the body portion in a direction opposite to the curved outer surface 126 and sized to be interference fit into a corresponding hole defined in a first PCB. The second end 134 extends approximately in the same direction as the first end 132. The curved outer surface 126, as best seen in FIG. 1B, defines a plane that will be approximately co-planer with the surface of the second PCB to enable connector 100 to be surface mounted to the second PCB.

As further seen in FIGS. 1A and 1B, connector 100 preferably has a pair of prongs on first end 132 and preferably a rounded surface on second end 134. The connector 100 is preferably formed by bending a stamped piece of metal roughly in its center along the longer sides. The second end 134 is folded over such that the pair of prongs is behind and under the flat second end 134 in plan view. The view of the connector 100 shown in FIG. 1A shows a pair of prongs 110 and 120 behind second end 134. The view of the connector in FIG. 1B shows the longer side of connector 100. As perhaps best seen in FIG. 2C, second end 134 preferably abuts the surface of the first PCB when the prongs 110 and 120 are press fit into the PCB to enable flow solder connection of second end 134 to the surface of the first PCB.

Connector 100 according to the present invention is designed to eliminate the problem of prior art SMT pins which tend to shift into misaligned position or even fall off the PCB as a consequence of undergoing solder reflow, especially during re-work procedures. The connector 100 according to the present invention eliminates this retention issue by combining through-hole technology with surface mount technology. As described above, this is provided in part by designing prongs 110 and 120 of a size to be press fit into matching holes drilled in the PCB to thereby retain the connector 100 in its proper location on the surface of the PCB. The size of each square prong 110, 120 and matching hole in the PCB is controlled tightly so that the fit is a slight interference fit. PCB damage is avoided because the nature of the PCB construction is to allow some compliance. That is, if the fit is not overly tight, the PCB will give sufficiently to accommodate the size of the prongs 110, 120.

FIG. 1C is a detailed view of the prongs 110 and 120 of the connector 100 shown in FIGS. 1A and 1B press fit inserted according to the present invention into round holes formed in holes 136 and 138 in a PCB 139. As seen in FIG. 1C, the interference fit between the edges of each prong and its corresponding hole is what retains the connector 100 on the surface of the PCB. Alternate techniques for retention a connector 100 on the surface of a PCB are well known in the art and may be include forming fins on the side of each prong, knurling each prong, or splitting and splaying each prong end. Another technique for retaining pins or prongs in a PCB comprised what is termed the “star” technique where vanes are formed on the side of the prongs that engage the interior surface of the hole (instead of the corners of a square as shown in FIG. 1C). The star technique is superior in some applications in that it is not susceptible to variance in insertion forces caused by dimensional variations in the prong or in the hole formed in the PCB. In other words, the vanes' engagement with the interior surface of the hole varies less with hole diameter than where the prong has a square cross sectional shape.

The length 140 of prongs 110 and 120 can be changed depending on the thickness of the PCB to which it is attached. As is best seen in FIG. 1A, the prongs 110 and 120 have a square cross-sectional shape in this embodiment. The overall height 150 of the connector body portion can also be changed as a function of the amount of space needed between adjacent PCBs. The stand-off distance between adjacent PCBs is a function of the size of the components mounted on each PCB, and may also be a function of the amount of heat that needs to be dissipated from one or both PCBs for optimal performance. FIGS. 1A and 1B also show a notch 160 formed on the curved outer surface 126 of connector 100 whose primary purpose is to aid in centering the connector 100 on its mating PCB, the second PCB, under solder reflow conditions. The self centering effect of the notch is made possible by surface tension effects of molten solder and the surfaces which it wets. Surfaces wetted by molten solder experience tensile forces pulling the surface toward toward the body of the solder. The notch divides the solder surface into two distinct sections, thus increasing the length of the solder wetted edge. The increase in the length of the wetted edge increases the surface tension forces pulling the connector into symmetric alignment with the solder pad during the molten solder phase of the solder reflow operation. The centering enhancement is dependent on the solder pad being designed to take advantage of the increase in wetted edge length.

The notch 160 can also be used to isolate sides 170 and 180 of the connector 100 for testing purposes. That is, each side may be sized to enable the surface mounting of each side to a different contact area on the surface of the second PCB. Consequently, power can be coupled through one side of connector 100 while the voltage can be sensed by a different circuit on the second PCB in a conventional way using the second side.

FIGS. 2A-2E show respective front, top, side, and bottom views of connector 100 along with their preferred dimensions. It should be noted that these dimensions are for purpose of illustration only, and other dimensions and shapes are equally useable without departing from the present invention. As seen in the side view of connector 100 shown in FIG. 2C, the connector body portion may define a U-shaped cross-section, and more generally, a box shaped cross-section. An important aspect of the shape of connector 100 is that it provide a minimum parasitic inductance between the two PCBs once the connector 100 is assembled between these boards.

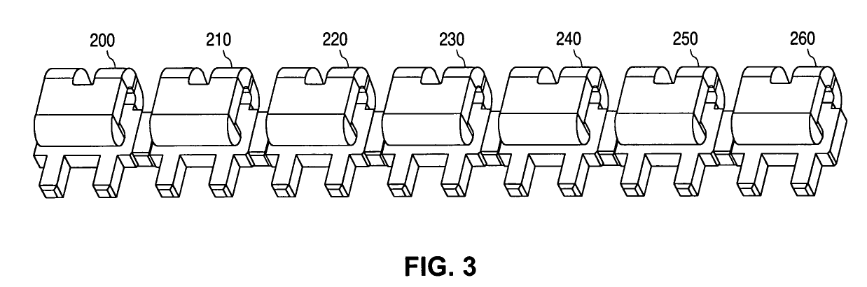

FIG. 3 illustrates a perspective view of a series of connectors 100 in a continuous coil format, according to an embodiment of the present invention. Connectors 200, 210, 220, . . . 260 are coupled to each other along the long side adjacent to each other. There is a reduction in cost due to this continuous coil format when compared to known connectors that use SMT or two-dimensional pin type connectors that are mounted using tape and reel packaging.

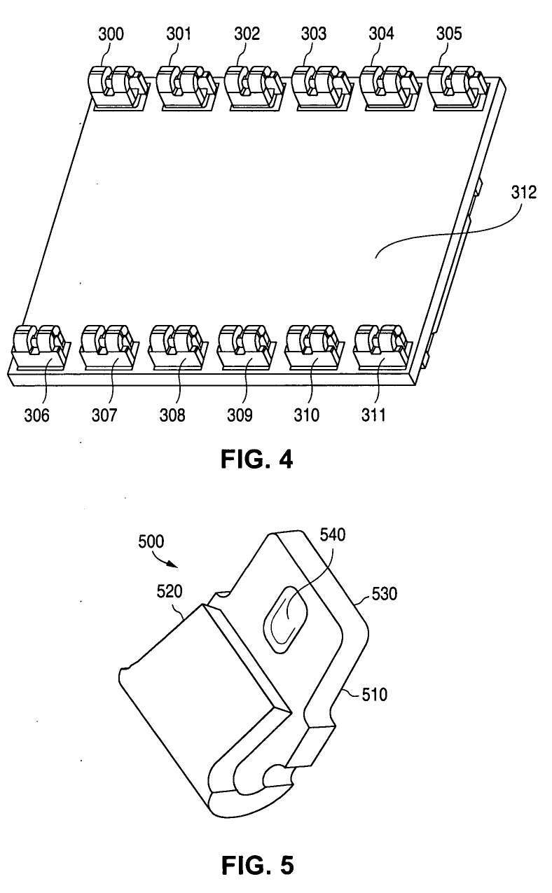

FIG. 4 is a perspective view of a pair of rows of SMT connectors 300, 301, 302, 311 installed on a PCB 312. It can be clearly seen from FIG. 4 that each connector has its top side folded over towards its prong side (not seen) toward the center of the PCB.

FIG. 5 is a perspective view of an alternate embodiment of the present invention wherein the connector includes a single tab for press fit insertion of the connector into a PCB slot. As seen in FIG. 5, connector 500 is similarly formed of a stamped piece of metal bent in the middle to form a first end 510 and a second end 520. The first end 510 is formed in the shape of a tab 530 instead of two square prongs. A dimple 540 is formed on the surface of the tab to provide retention of the connector 500 in a slot formed in a PCB that is appropriately sized so that the dimple 540 provides an interference fit for the tab 530 in the slot formed in the PCB. As is known in the art, the retention provided dimple 540 can also be provided by replacing the dimple with a barb, with knurling on the tab, or by forming the slot in the PCB to have a slightly smaller size than size of tab 530. The preferred embodiment remains using two prongs instead of a tab because holes in a PCB cost less to manufacture than a slot.

Another embodiment of the present invention is to place solder balls on the end mating surface of the connector according to the present invention that is designed to be SMT connected to a second PCB. The purpose of such solder balls is to melt during the fastening of the second PCB to the end user mating surface to minimize the effect of variations in the height of the assembly generated by the connectors and the host PCB. This variation in co-planarity is otherwise a potential problem when installing the second PCB on the host PCB. Especially in a product having a number of connectors according to the present invention arranged approximately so as to define a common plane corresponding to the surface of the second PCB, some variations in contact points on the surfaces of these connectors from an ideal plane is to be expected. Another possible variation according to the present invention is to make the sides of the connector wavy so that they will exhibit inherent compliance during manufacturing. It is often the case that the connector is so stiff that it could theoretically contribute to solder joint failures when the system of stacked PCBs and connectors are exposed to cycling extremes of temperature. Like the improvement provided by adding solder balls to the end user mating surface of the connector, providing wavy sides also may improve the reliability of the connection of one PCB to another using connectors according to the present invention.

According to one embodiment, the present connector is also used as a contact internal to a linear actuated electric switch. According to another embodiment, the present connector is also used as a contact point between two or more electrical devices or circuits that are not necessarily soldered to one another.

The invention has now been explained with regard to specific embodiments. Variations on these embodiments and other embodiments may be apparent to those of skill in the art. It is therefore intended that the invention not be limited by the discussion of specific embodiments. It is understood that the examples and embodiments described herein are for illustrative purposes only and that various modifications or changes in light thereof will be suggested to persons skilled in the art and are to be included within the spirit and purview of this application and scope of the appended claims.

1. A connector for connecting a first printed circuit board to a second printed circuit board, said connector comprising:
a body portion formed of a strip of conductive material bent in a central area thereof to define a curved outer surface and a hollow cross-section and having a first end and a second end, said first end having at least one prong extending out therefrom in a direction opposite to said curved outer surface and sized to be mechanically held in a corresponding hole defined in said first printed circuit board, said second end extending approximately in the same direction as said first end, said curved outer surface defining a plane such that said curved outer surface is enabled to be surface mounted to said second printed circuit board when the surface of said second printed circuit board is positioned approximately parallel to the adjacent surface of said first printed circuit board;
such that said connector enables in-hole mounting of said connector to said first printed circuit board and enables surface mounting of said connector to said second printed circuit board.

2. The connector of claim 1 wherein said one or more prongs is sized to be interference fit into said corresponding hole defined in said first printed circuit board.

3. The connector of claim 1 wherein said one or more prongs comprises two prongs, and wherein each said prong has a square cross section.

4. The connector of claim 1 wherein said one or more prongs comprises a tab and wherein said hole is in the shape of a slot.

5. The connector of claim 4 wherein said tab includes a dimple for providing an interference fit of said tab in said slot.

6. The connector of claim 1 wherein a notch is formed in said curved outer surface to form two sides, each side sized to enable the surface mounting of said side to a different contact area on the surface of said second circuit board.

7. The connector of claim 1 wherein said body portion is sized so as to define a predetermined stand-off distance between said first printed circuit board and said second printed circuit board when said one or more prongs is mechanically held in said corresponding hole and said outer curved surface is surface mounted to said second printed circuit board.

8. The connector of claim 1 wherein said strip of conductive material defines an approximately U-shaped cross-section.

9. The connector of claim 1 wherein said strip of conductive material defines an approximately box-shaped cross-section.

10. The connector of claim 1 wherein said strip of conductive material is bent so as to substantially reduce the parasitic inductance of said connector.

11. A connector for connecting a first printed circuit board and a second printed circuit board, said connector comprising:
a pair of prongs extending from a first end of said connector, each prong sized to be mechanically held in a corresponding hole defined in said first printed circuit board;
a second end of said connector opposite to said first end folded towards said first end such that said second end limits how far each said prong can extend into said corresponding hole;
wherein the surface of said connector opposite to said first and second ends is shaped so as to enable said connector to be surface mounted to a second printed circuit board when the surface of said second printed circuit board is positioned approximately parallel to the adjacent surface of said first printed circuit board; and
a notch formed on the surface of said connector opposite to said first and second ends in the area of said fold.

12. The connector of claim 11, wherein said pair of prongs has a length that is a function of the thickness of said first printed circuit board.

13. The connector of claim 12, wherein each prong in said pair of prongs has a square cross-sectional shape.

14. The connector of claim 11, wherein said notch improves the self-centering of said connector on said second printed circuit board under solder reflow conditions.

15. The connector of claim 14, wherein said notch forms two sides, each side sized to enable the surface mounting of said side to a different contact area on the surface of said second circuit board.

16. The connector of claim 11, wherein said surface of said connector opposite to said first and second ends in the area of said fold defines a planar surface such that said planar surface is enabled to be surface mounted to said second printed circuit board when the surface of said second printed circuit board is positioned approximately parallel to the adjacent surface of said first printed circuit board.

17. (canceled)

18. The connector of claim 11, wherein said connector is used as an unsoldered contact point between said first printed circuit board and a second printed circuit board.

19. The connector of claim 2 wherein said second end abuts the surface of said first printed circuit board when said one or more prongs is interference fit into said corresponding hole.
